(19) United States
(12) Patent Application Publication
(10) Pub. No.: US 2025/0244673 A1
(43) Pub. Date: Jul. 31, 2025

(54) HARDMASK COMPOSITION, HARDMASK LAYER, AND METHOD OF FORMING PATTERNS

(71) Applicant: SAMSUNG SDI CO., LTD., Yongin-si (KR)

(72) Inventors: Seulgi JEONG, Suwon-si (KR); Sunhae KANG, Suwon-si (KR)

(21) Appl. No.: 19/019,742

(22) Filed: Jan. 14, 2025

(30) Foreign Application Priority Data
Jan. 26, 2024 (KR) 10-2024-0012616

(51) Int. Cl. G03F 7/20

(52) U.S. Cl. CPC G03F 7/2016

(57) ABSTRACT

A hardmask layer including a cured product of the hardmask composition, and a method of forming patterns that uses the hardmask layer including a cured product of the hardmask composition, the hardmask composition includes a polymer including a structural unit represented by Chemical Formula 1; and a solvent,

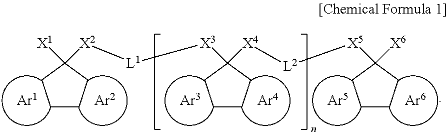

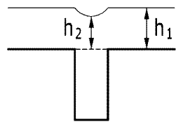

### CROSS-REFERENCE TO RELATED APPLICATION

This application claims priority to and the benefit of Korean Patent Application No. 10-2024-0012616 filed in the Korean Intellectual Property Office on Jan. 26, 2024, the entire contents of which are incorporated herein by reference.

### BACKGROUND

### 1. Field

Embodiments relate to a hardmask composition, a hardmask layer including a cured product of the hardmask composition, and a method of forming a pattern using the hardmask composition.

### 2. Description of the Related Art

Recently, the semiconductor industry has developed an ultra-fine technique having a pattern of several to several tens nanometer size. Such ultrafine techniques may use effective lithographic techniques.

Some lithographic techniques may include providing a material layer on a semiconductor substrate; coating a photoresist layer thereon; exposing and developing the same to provide a photoresist pattern; and etching a material layer using the photoresist pattern as a mask.

### SUMMARY

Embodiments are directed to a hardmask composition, including a polymer represented by Chemical Formula 1; and a solvent,

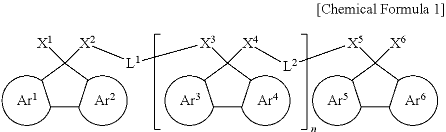

wherein, in Chemical Formula 1, Ar¹ to Ar⁶ are each independently a substituted or unsubstituted C6 to C20 aromatic hydrocarbon ring, X¹ to X⁶ are each independently a substituted or unsubstituted C6 to C20 aromatic hydrocarbon group, L¹ and L² are each independently a divalent organic group, and n is an integer of 1 to 100.
Ar¹ to Ar⁶ may each independently be a substituted or unsubstituted aromatic hydrocarbon ring of Group 1,

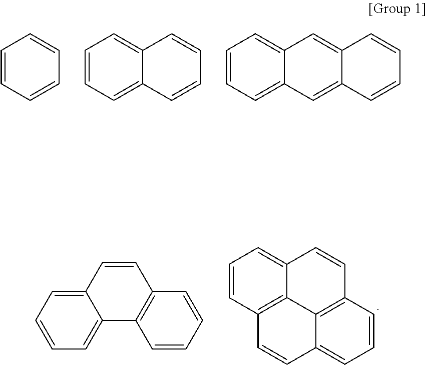

X¹ to X⁶ may each independently include a substituted or unsubstituted moiety of Group 2,

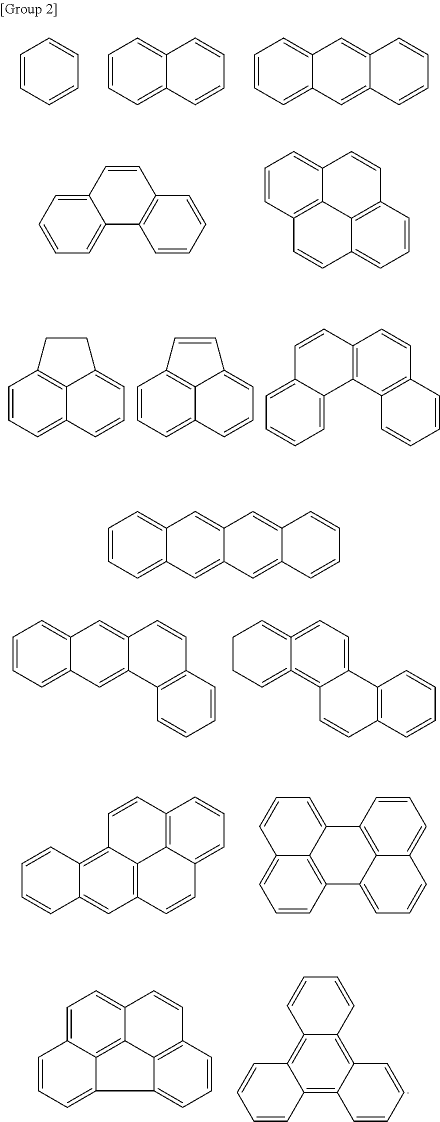

L¹ and L² may each independently be represented by one of Chemical Formula 2 to Chemical Formula 5,

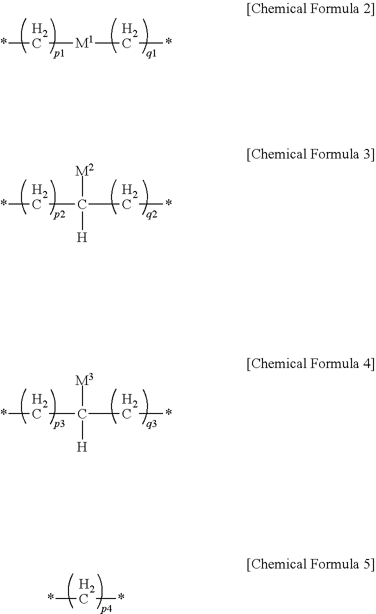

in Chemical Formula 2 to Chemical Formula 5, M¹ to M⁴ may each independently include a substituted or unsubstituted moiety of Group 3, p1 to p3 and q1 to q3 may each independently be an integer of 0 to 4, p4 may be an integer of 1 to 5, and * is a linking point,

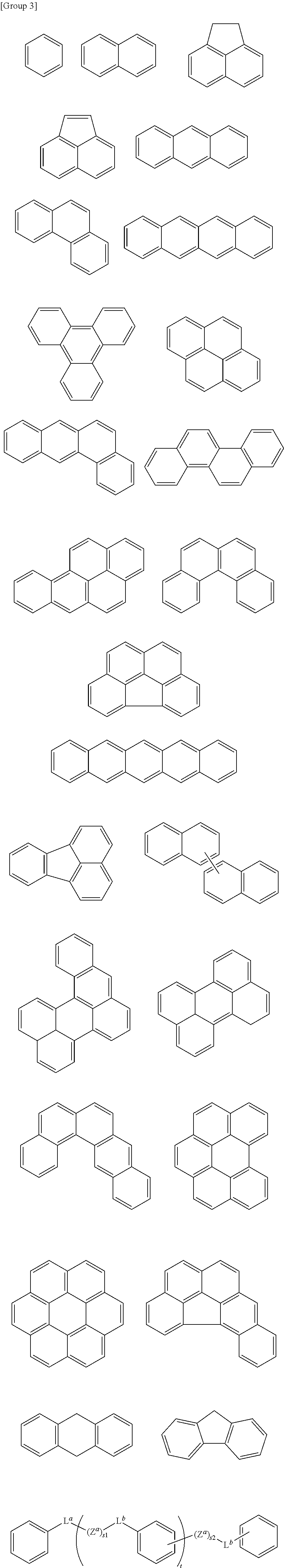

in Group 3, L^{a} to L^{c} may each independently be a single bond, a substituted or unsubstituted C1 to C10 alkylene group, a substituted or unsubstituted C2 to C10 alkenylene group, or a combination thereof, Z^{a} and Z^{b} may each independently be, —O—, —S—, —SO₂—, —C(═O)—, or —NR^{a}—, in which R^{a} may be hydrogen, a substituted or unsubstituted C1 to C10 alkyl group, or a substituted or unsubstituted C6 to C20 aryl group, s1 and s2 may each independently be 0 or 1, and t may be an integer of 0 to 4.

L¹ and L² may each independently be represented by one of Chemical Formula 7 to Chemical Formula 13, in which * is a linking point,

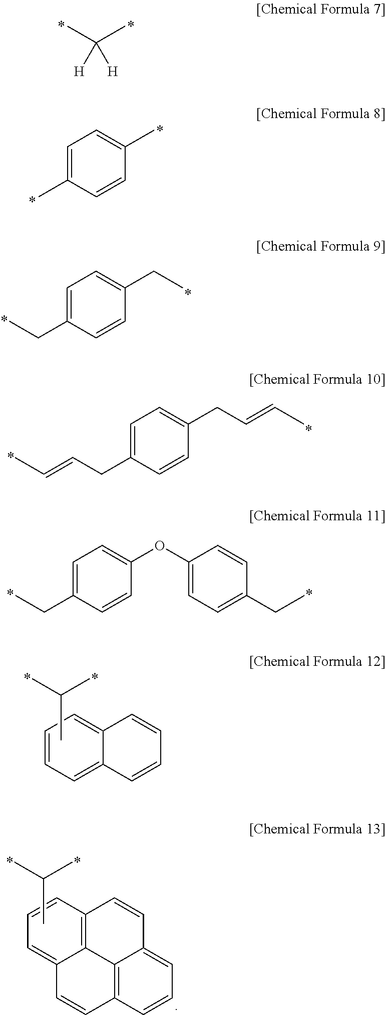

The polymer may be represented by one of Chemical Formula 1-1 to Chemical Formula 1-3,

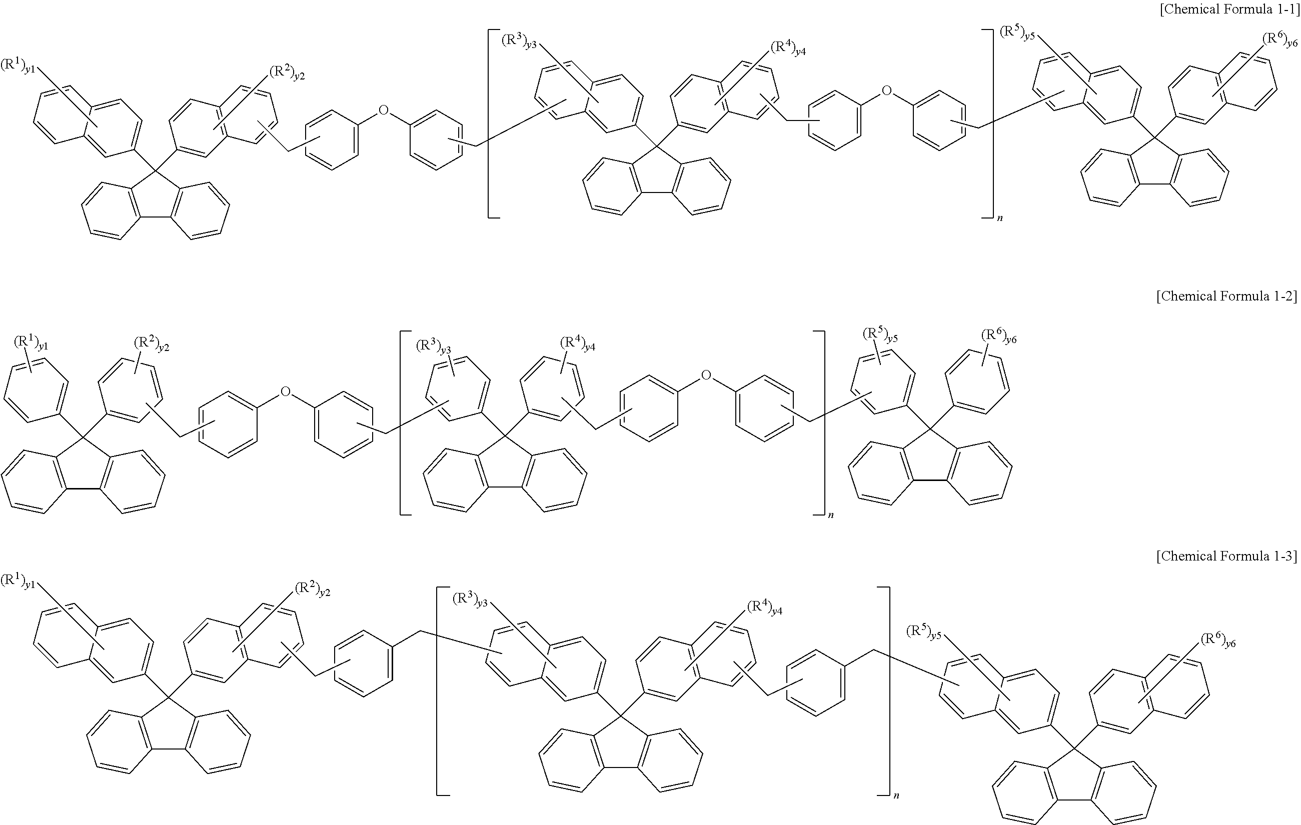

in Chemical Formula 1-1 to Chemical Formula 1-3, R¹ to R⁶ may each independently be deuterium, a hydroxy group, a substituted or unsubstituted C1 to C5 alkoxy group, a substituted or unsubstituted C1 to C5 alkyl group, or a combination thereof, y1 to y6 may each independently be an integer of 1 to 4, and n may be an integer of 1 to 100.

The polymer may have a weight average molecular weight of about 1,000 g/mol to about 10,000 g/mol.

The polymer may be included in an amount of about 0.1 wt % to about 30 wt %, based on a total weight of the hardmask composition.

The solvent may be propylene glycol, propylene glycol diacetate, methoxy propanediol, diethylene glycol, diethylene glycol butylether, tri (ethylene glycol) monomethylether, propylene glycol monomethylether, propylene glycol monomethylether acetate, cyclohexanone, ethyllactate, gamma-butyrolactone, N,N-dimethyl formamide, N,N-dimethyl acetamide, N-methyl-2-pyrrolidone, acetylacetone, or ethyl 3-ethoxypropionate.

The embodiments may be realized by providing a hardmask layer including a cured product of the hardmask composition.

The embodiments may be realized by providing a method forming patterns, the method including providing a material layer on a substrate; applying the hardmask composition as claimed in claim 1 to the material layer; heat-treating the hardmask composition to form a hardmask layer; forming a photoresist layer on the hardmask layer; exposing and developing the photoresist layer to form a photoresist pattern; selectively removing the hardmask layer using the photoresist pattern to expose a portion of the material layer; and etching an exposed part of the material layer.

The heat-treating may be performed at about 100° C. to about 1,000° C.

### BRIEF DESCRIPTION OF THE DRAWING

Features will become apparent to those of skill in the art by describing in detail exemplary embodiments with reference to the attached drawing in which:

The FIGURE is a reference diagram schematically showing a cross-section of a hardmask layer to explain a method for evaluating planarization characteristics.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing FIGURE, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout. As used herein, the term “or” is not necessarily an exclusive term, e.g., “A or B” would include A, B, or A and B. As used herein, hydrogen substitution (—H) may include deuterium substitution (-D) or tritium substitution (-T). For example, any hydrogen in any compound described herein may be protium, deuterium, or tritium (e.g., based on natural or artificial substitution).

As used herein, when a definition is not otherwise provided, ‘substituted’ may refer to replacement of a hydrogen atom of a compound by a substituent selected from a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, C9 to C30 allylaryl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof.

In addition, adjacent two substituents of the substituted halogen atom (F, Br, Cl, or I), the hydroxy group, the nitro group, the cyano group, the amino group, the azido group, the amidino group, the hydrazino group, the hydrazono group, the carbonyl group, the carbamyl group, the thiol group, the ester group, the carboxyl group or the salt thereof, the sulfonic acid group or the salt thereof, the phosphoric acid or the salt thereof, the C1 to C30 alkyl group, the C2 to C30 alkenyl group, the C2 to C30 alkynyl group, the C6 to C30 aryl group, the C7 to C30 arylalkyl group, the C1 to C30 alkoxy group, the C1 to C20 heteroalkyl group, the C3 to C20 heteroarylalkyl group, the C3 to C30 cycloalkyl group, the C3 to C15 cycloalkenyl group, the C6 to C15 cycloalkynyl group, the C2 to C30 heterocyclic group may be fused to form a ring.

As used herein, when a definition is not otherwise provided, “aromatic hydrocarbon ring” refers to a group including at least one hydrocarbon aromatic moiety, and includes a form in which hydrocarbon aromatic moieties are linked by a single bond, a non-aromatic fused ring form in which hydrocarbon aromatic moieties are fused directly or indirectly, or a combination thereof as well as a non-fused aromatic hydrocarbon ring or a condensed aromatic hydrocarbon ring.

For example, the substituted or unsubstituted aromatic hydrocarbon ring may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a combination thereof, or a combined fused ring of the foregoing groups.

As used herein, when a definition is not otherwise provided, “combination” means mixing or copolymerization.

As used herein, when a definition is not otherwise provided, the polymer may include both an oligomer and a polymer.

Unless otherwise specified in the present specification, the “weight average molecular weight” is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

In the semiconductor industry, a size of chips may be reduced. Accordingly, the line width of the resist patterned in lithography technology may be tens of nanometers in size. A height that can withstand the line width of the resist pattern may be limited, and there are cases where the resists may not have sufficient resistance in the etching step. In order to compensate for this, an auxiliary layer, which is called a hardmask layer, may be used between a material layer to be etched and a photoresist layer. This hardmask layer may serve as an interlayer that transfers the fine pattern of the photoresist to the material layer through selective etching. Therefore, the hardmask layer may have etch resistance and heat resistance to withstand the etching process required for pattern transfer.

In addition, in order to realize a fine pattern of photoresist, forming multiple patterns may be essential, and gap-fill characteristics that fill the composition within the fine pattern without voids may be required. In addition, if there is a step in the substrate to be processed or if a patterned region and an unpatterned region exist on the same wafer, planarization characteristics may be required to form a flat surface of the hardmask layer.

Some other hardmask layers may be formed in a chemical or physical deposition method and may have a problem of low economic efficiency due to large-scale equipment and a high process cost. Therefore, a method of forming a hardmask layer by a spin-coating technique has recently been considered. The spin-coating technique may be easier to process than the other methods and in addition, may help secure excellent gap-fill characteristics and planarization characteristics of a hardmask layer formed therefrom.

In a hardmask layer formed using the spin-coating technique, the required etch resistance could be somewhat lowered. Accordingly, a hardmask composition according to an embodiment may be applied using the spin-coating technique and may secure equivalent etch resistance to that of the hardmask layer formed in the chemical or physical deposition method.

In order to help improve the etch resistance of the hardmask layer, maximizing a carbon content of a hardmask composition may be considered. As a carbon content of a polymer included in the hardmask composition is maximized, solubility in solvents could decrease. According to an embodiment, the carbon content maximization of a polymer included in the hardmask composition may not only improve the etch resistance of the hardmask layer formed of the hardmask composition but may also help secure high solubility of the polymer in the solvents.

The hardmask composition according to some embodiments may include a polymer with a high carbon content but a low molecular weight, and thus may have excellent gap-fill characteristics for fine patterns. In addition, by including a linking group with high fluidity in the polymer, the polymer may have excellent solubility in solvents, and the planarization characteristics of the hardmask layer formed from the composition may be improved.

The hardmask composition according to some embodiments may include a polymer represented by Chemical Formula 1, and a solvent.

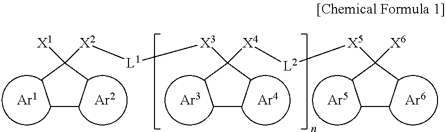

In Chemical Formula 1, Ar¹ to Ar⁶ may each independently be or include, e.g., a substituted or unsubstituted C6 to C20 aromatic hydrocarbon ring,

X¹ to X⁶ may each independently be or include, e.g., a substituted or unsubstituted C6 to C20 aromatic hydrocarbon group.

L′ and L² may each independently be or include, e.g., a divalent organic group.

n may be an integer of 1 to 100, and an average value of n may be a value of 1 to 10 (e.g., an average value of n of all molecules in the polymer of the composition may be 1 to 10).

The polymer may include moieties including aromatic hydrocarbon rings, e.g., X¹, X², Ar¹, and Ar² and X³, X⁶, Ar⁵, and Ar⁶, at both ends, and thus gap-fill characteristics of the composition and heat resistance of the hardmask layer formed from the composition may be improved. In addition, the moieties may have a three-dimensional structure and may include a fluid linking group represented by L¹ and L², so that the polymer has excellent solubility in solvents and coating properties. Accordingly, the planarization characteristics of the hardmask layer formed from the composition may be improved.

In an implementation, Ar¹ to Ar⁶ may each independently be or include a substituted or unsubstituted aromatic hydrocarbon ring of Group 1, e.g., a substituted or unsubstituted benzene, a substituted or unsubstituted naphthalene, or a substituted or unsubstituted pyrene.

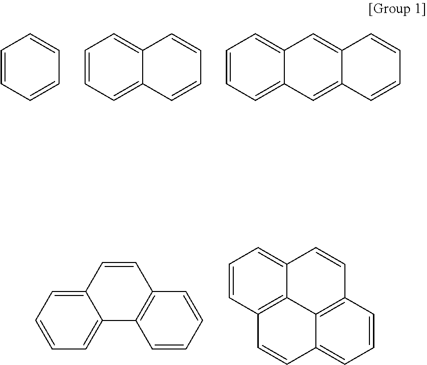

In an implementation, X¹ to X⁶ may each independently include, e.g., a substituted or unsubstituted moiety of Group 2, e.g., a substituted or unsubstituted benzene, a substituted or unsubstituted naphthalene, a substituted or unsubstituted phenanthrene, a substituted or unsubstituted anthracene, a substituted or unsubstituted pyrene, or a combination thereof or a substituted or unsubstituted benzene, a substituted or unsubstituted naphthalene, a substituted or unsubstituted pyrene, or a combination thereof.

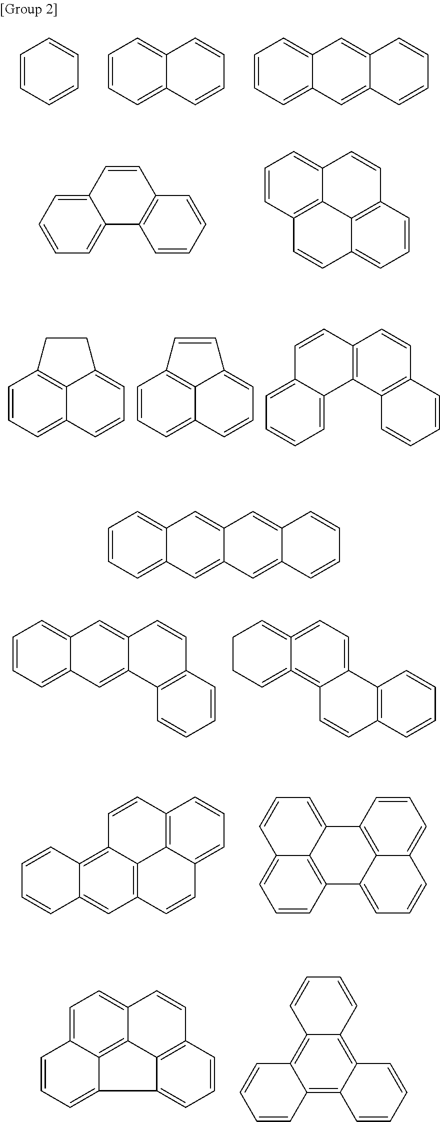

In an implementation, the moieties of X¹ to X⁶ may each independently be substituted with deuterium, a halogen atom, an amino group, a hydroxy group, a substituted or unsubstituted C1 to C10 alkoxy group, a substituted or unsubstituted C1 to C10 alkyl group, a substituted or unsubstituted C3 to C10 cycloalkenyl group, a substituted or unsubstituted C6 to C20 aryl group, or a combination thereof.

In an implementation, L¹ and L² may each independently be represented by one of Chemical Formula 2 to Chemical Formula 6.

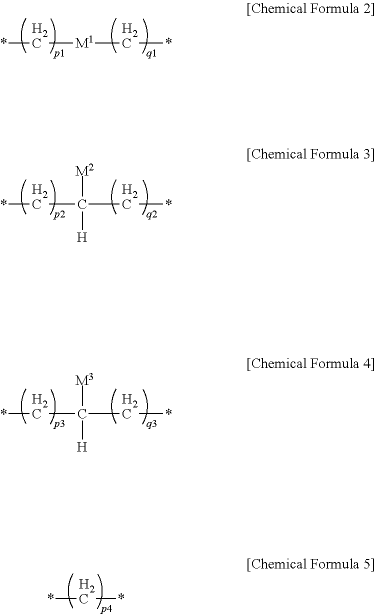

In Chemical Formula 2 to Chemical Formula 5, M¹ to M⁴ may each independently be one of substituted or unsubstituted moieties of Group 3, e.g., a substituted or unsubstituted benzene, a substituted or unsubstituted naphthalene, a substituted or unsubstituted anthracene, a substituted or unsubstituted phenanthrene, a substituted or unsubstituted pyrene, or a combination thereof or a substituted or unsubstituted benzene, a substituted or unsubstituted naphthalene, or a combination thereof.

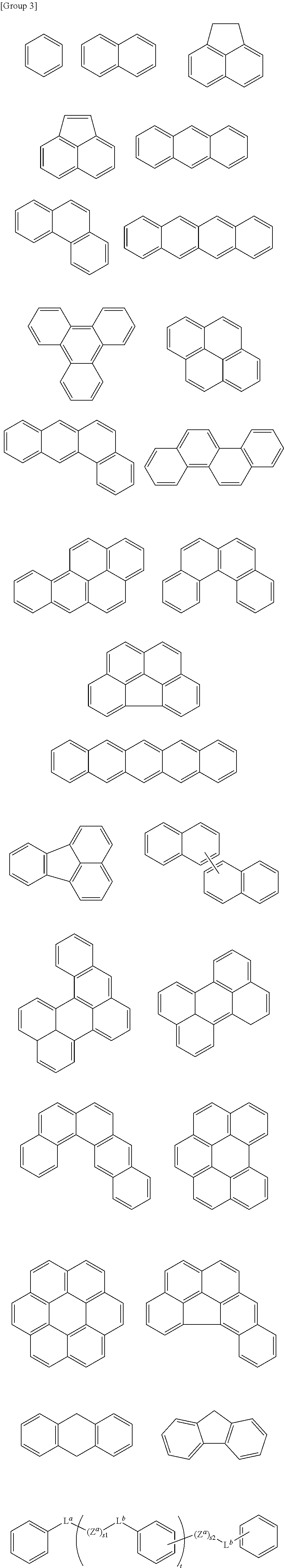

In Group 3, L^{a} to L^{c} may each independently be, e.g., a single bond, a substituted or unsubstituted C1 to C10 alkylene group, a substituted or unsubstituted C2 to C10 alkenylene group, or a combination thereof, e.g., single bond or a substituted or unsubstituted C1 to C5 alkylene group, or a combination thereof.

In an implementation, Z^{a} and Z^{b} may each independently be, e.g., —O—, —S—, —SO₂—, —C(═O)—, or —NR^{a}— (wherein, R^{a} may be, e.g., hydrogen, a substituted or unsubstituted C1 to C10 alkyl group, or a substituted or unsubstituted C6 to C20 aryl group), e.g., —O—, or —S—.

In an implementation, s1 and s2 may each independently be 0 or 1 and t may be an integer of 0 to 4.

In an implementation, in Chemical Formula 2 to Chemical Formula 4, p1 to p3 and q1 to q3 may each independently be an integer of 0 to 4, e.g., an integer of 0 to 3, 0 or 1.

In an implementation, in Chemical Formula 5, p4 may be an integer of 1 to 5, e.g., an integer of 1 to 3, 1, or 2.

In an implementation, in Chemical Formula 2 to Chemical Formula 5, * is a linking point:

In an implementation, L¹ and L² may each independently be represented by one of Chemical Formula 7 to Chemical Formula 13.

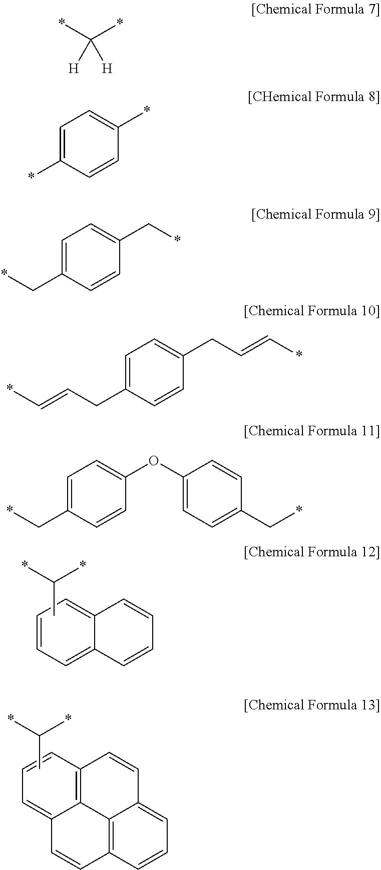

In Chemical Formula 7 to Chemical Formula 13, * is a linking point.

In an implementation, n in Chemical Formula 1 may be an integer of 1 to 100, and an average value of n may be a value of 1 to 10. In an implementation, n may be an integer of 1 to 50, e.g., an integer of 1 to 40 or 1 to 30, and the average value of n may be a value of 1 to 10, e.g., a value of 1 to 7 or 1 to 5. The average value of n means the number calculated by dividing the weight average molecular weight of the polymer by the molecular weight of the structural unit that repeats within the polymer.

In an implementation, the polymer may be represented by one of Chemical Formula 1-1 to Chemical Formula 1-3.

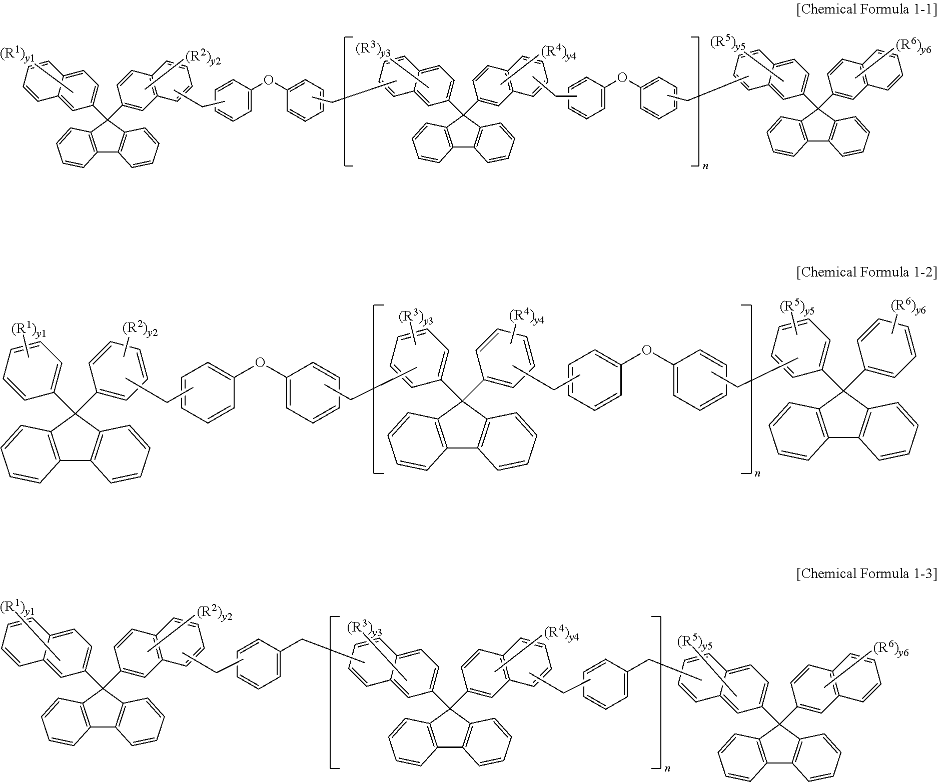

In Chemical Formula 1-1 to Chemical Formula 1-3, R¹ to R⁶ may each independently be or include, e.g., deuterium, a hydroxy group, a substituted or unsubstituted C1 to C5 alkoxy group, a substituted or unsubstituted C1 to C5 alkyl group, or a combination thereof or deuterium, a hydroxy group, a substituted or unsubstituted C1 to C5 alkoxy group, or a combination thereof.

In Chemical Formula 1-1 to Chemical Formula 1-3, y1 to y6 may each independently be an integer of 1 to 4, e.g., an integer of 1 to 3, 1, or 2.

In Chemical Formula 1-1 to Chemical Formula 1-3, the average value of n may be 1 to 10, e.g., a value of 1 to 7 or 1 to 5.

The polymer may have a weight average molecular weight of, e.g., about 1,000 g/mol to about 100,000 g/mol. In an implementation, the polymer may have a weight average molecular weight of, e.g., about 1,000 g/mol to about 9,500 g/mol, about 1,000 g/mol to about 9,000 g/mol, about 1,200 g/mol to about 9,000 g/mol, about 1,200 g/mol to about 8,000 g/mol, about 1,500 g/mol to about 8,000 g/mol, about 1,500 g/mol to about 7,000 g/mol, about 1,500 g/mol to about 6,000 g/mol, about 1,500 g/mol to about 5,000 g/mol, or about 1,500 g/mol to about 3,000 g/mol. Maintaining a weight average molecular weight within the above ranges may help ensure that the carbon content and solubility in the solvent of the hardmask composition including the polymer may be adjusted, and thereby a hardmask layer exhibiting optimal gap-filling and planarization characteristics may be prepared.

The polymer may be included in an amount of, e.g., about 0.1 wt % to about 30 wt %, based on a total weight of the hardmask composition. In an implementation, the polymer may be included in an amount of about 0.2 wt % to about 30 wt %, e.g., about 0.5 wt % to about 30 wt %, about 1 wt % to about 30 wt %, about 1.5 wt % to about 25 wt %, or about 2 wt % to about 20 wt %. Maintaining the amount of polymer within the above ranges may help ensure that a thickness, a surface roughness, and a planarization degree of the hardmask may be easily adjusted.

The hardmask composition according to an implementation may include a solvent, and in an implementation, the solvent may be, e.g., propylene glycol, propylene glycol diacetate, methoxy propanediol, diethylene glycol, diethylene glycol butyl ether, tri (ethylene glycol) monomethyl ether, propylene glycol monomethyl ether, propylene glycol monomethyl ether acetate, cyclohexanone, ethyl lactate, gamma-butyrolactone, N,N-dimethylformamide, N,N-dimethylacetamide, N-methyl-2-pyrrolidone, acetylacetone, ethyl 3-ethoxypropionate, or the like. In an implementation, the solvent mat include a suitable solvent as long as it has sufficient solubility sufficient solubility or dispersibility with respect to the polymer may be used.

In an implementation, the hardmask composition may further include an additive, e.g., a surfactant, a crosslinking agent, a thermal acid generator, and a plasticizer.

The surfactant may include, e.g., a fluoroalkyl compound, alkylbenzenesulfonate, alkylpyridinium salt, polyethylene glycol, a quaternary ammonium salt, or the like.

The crosslinking agent may include, e.g., a melamine, a substituted urea, or a polymer crosslinking agent. In an implementation, it may be a crosslinking agent having at least two crosslinking substituents, e.g., methoxymethylated glycoruryl, butoxymethylated glycoruryl, methoxymethylated melamine, butoxymethylated melamine, methoxymethylated benzoguanamine, butoxy methylated benzoguanamine, methoxymethylated urea, butoxymethylated urea, methoxymethylated thiourea, or butoxymethylated thiourea.

In an implementation, as the crosslinking agent, a crosslinking agent having high heat resistance may be used. The crosslinking agent having high heat resistance may include a compound containing a crosslinking substituent having an aromatic ring (e.g., a benzene ring or a naphthalene ring) in the molecule.

In an implementation, the thermal acid generator may include an acid compound, e.g., p-toluenesulfonic acid, trifluoromethanesulfonic acid, pyridinium p-toluenesulfonic acid, salicylic acid, sulfosalicylic acid, citric acid, benzoic acid, hydroxybenzoic acid, naphthalenecarboxylic acid or 2,4,4,6-tetrabromocyclohexadienone, benzointosylate, 2-nitrobenzyltosylate, or other organic sulfonic acid alkyl esters.

According to some embodiments, a hardmask layer including a cured product of the aforementioned hardmask composition may be provided.

Hereinafter, a method of forming patterns using the aforementioned hardmask composition is described.

A method of forming patterns according to some embodiments may include, e.g., providing a material layer on a substrate, applying a hardmask composition including the aforementioned polymer and solvent to the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a part of the material layer, and etching the exposed part of the material layer.

The substrate may be, e.g., silicon wafer, a glass substrate, or a polymer substrate. The material layer may be a material to be finally patterned, e.g., a metal layer such as an aluminum layer and a copper layer, a semiconductor layer such as a silicon layer, or an insulation layer such as a silicon oxide layer and a silicon nitride layer. The material layer may be formed through a method such as a chemical vapor deposition (CVD) process.

The hardmask composition is the same as described above, and may be applied by spin-on coating in a form of a solution. Herein, an application thickness of the hardmask composition may be, e.g., about 50 Å to about 200,000 Å.

The heat-treating of the hardmask composition may be performed, e.g., at about 100° C. to about 1,000° C. for about 10 seconds to about 1 hour. In an implementation, the heat-treating of the hardmask composition may include a plurality of heat-treating processes, e.g., a first heat-treating process and a second heat-treating process.

In an implementation, the heat-treating of the hardmask composition may include, e.g., one heat-treating process performed at about 100° C. to about 1,000° C. for about 10 seconds to about 1 hour. In an implementation, the heat-treating may be performed under an atmosphere of air or nitrogen, or an atmosphere having an oxygen concentration of about 1 wt % or less.

In an implementation the heat-treating of the hardmask composition may include, e.g., a first heat-treating process performed at about 100° C. to about 1,000° C., about 100° C. to about 800° C., about 100° C. to about 500° C., or about 150° C. to about 400° C. for about 30 seconds to about 1 hour or about 30 seconds to about 30 minutes, about 30 seconds to about 10 minutes, or 30 seconds to about 5 minutes.

In an implementation, the heat-treating may include a second heat-treating process that is consecutively performed, e.g., at about 100° C. to about 1,000° C., about 300° C. to about 1,000° C., about 500° C. to about 1,000° C., or about 500° C. to about 600° C. for about 30 seconds to about 1 hour, e.g., about 30 seconds to about 30 minutes, about 30 seconds to about 10 minutes, or about 30 seconds to 5 minutes. In an implementation, the first and second heat-treating processes may be performed under an air or nitrogen atmosphere or may be performed under an atmosphere with an oxygen concentration of about 1 wt % or less.

By performing at least one of the steps of heat-treating the hardmask composition at a high temperature of 200° C. or higher, high etch resistance capable of withstanding etching gas and chemical liquid exposed in subsequent processes including the etching process may be exhibited.

In an implementation, the forming of the hardmask layer may include a UV/Vis curing process and/or a near IR curing process.

In an implementation, the forming of the hardmask layer may include at least one of a first heat-treating process, a second heat-treating process, a UV/Vis curing process, and a near IR curing process, or may include two or more processes consecutively.

In an implementation, the method may further include forming a silicon-containing thin layer on the hardmask layer. The silicon-containing thin layer may be formed of a material, e.g., SiCN, SiOC, SION, SiOCN, SiC, SiO, SiN, or the like.

In an implementation, the method may further include forming a bottom antireflective coating (BARC) on the silicon-containing thin layer or on the hardmask layer before forming the photoresist layer.

In an implementation, exposure of the photoresist layer may be performed using, e.g., ArF, KrF, or EUV. After exposure, heat-treating may be performed at about 100° C. to about 700° C.

In an implementation, the etching process of the exposed part of the material layer may be performed through a dry etching process using an etching gas. In an implementation, the etching gas may be, e.g., N₂/O₂, CHF₃, CF₄, Cl₂, BCl₃, or a mixed gas thereof.

The etched material layer may be formed in a plurality of patterns, and the plurality of patterns may include a metal pattern, a semiconductor pattern, an insulation pattern, or the like, e.g., diverse patterns of a semiconductor integrated circuit device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Synthesis of Polymer

### Synthesis Example 1

A polymerization reaction was performed by adding 1.8 mol of 9,9-bis(6-hydroxy-2-naphthyl) fluorene, 1 mol of 4,4′-oxybis((methoxymethyl)benzene, 123 g of propylene glycol monomethyl ether acetate (PGMEA), and 0.5 g of diethylsulfate to a flask and then, stirring the mixture at 100° C.

After the polymerization reaction was completed, an intermediate product therefrom was slowly cooled to ambient temperature, and 40 g of distilled water and 400 g of methanol were added thereto and then, vigorously stirred and allowed to stand. After removing a supernatant therefrom, precipitates therein were dissolved in 80 g of cyclohexanone and then, vigorously stirred by using 320 g of methanol and allowed to stand (primary). Herein, after removing the obtained supernatant again, the precipitates therein were dissolved in 80 g of cyclohexanone (secondary). The primary and secondary processes were regarded as one purification process, which was repeated three times. The purified polymer was dissolved in 80 g of cyclohexanone, and the methanol and the distilled water remaining in the solution were removed under a reduced pressure to obtain a polymer represented by Chemical Formula 1-4 (Mw: 3,000 g/mol).

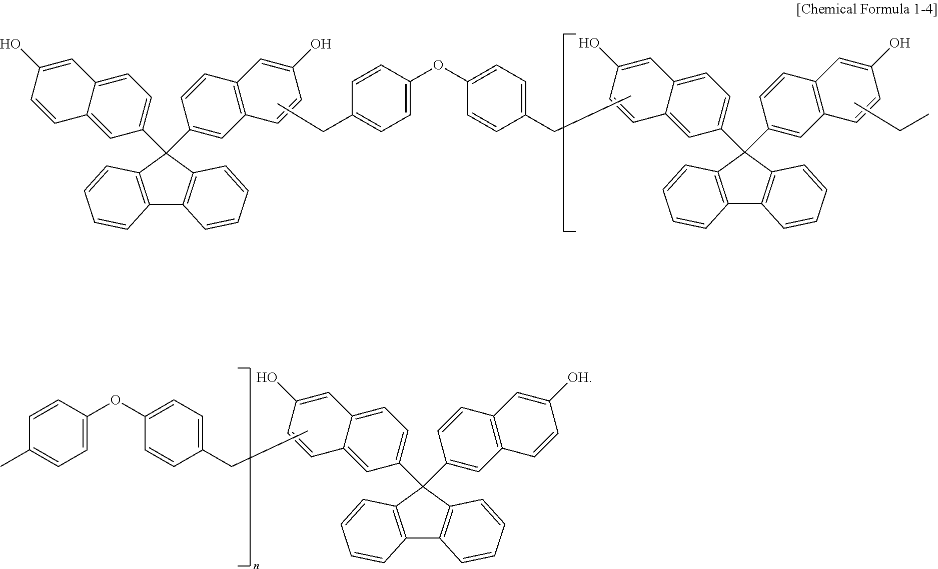

### Synthesis Example 2

A polymer represented by Chemical Formula 1-5 (Mw: 3,400 g/mol) was obtained in the same manner as in Synthesis Example 1 except that 1.6 mol of 9,9-bis(3,4-dihydroxyphenyl) fluorene was used instead of 1.8 mol of the 9,9-bis(6-hydroxy-2-naphtyl) fluorene, and 1 mol of 4,4′-oxybis((methoxymethyl)benzene) was used.

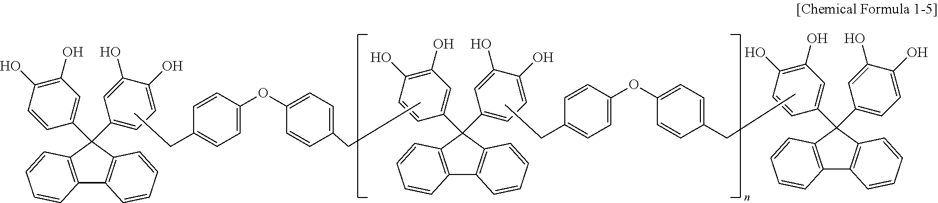

### Synthesis Example 3

A polymerization reaction was performed by adding 1.8 mol of 9,9-bis(6-hydroxy-2-naphthyl) fluorene, 1 mol of 1,4-bis(methoxymethyl)benzene, 123 g of propylene glycol monomethyl ether acetate (PGMEA), and 0.5 g of diethylsulfate to a flask and then, stirring the mixture at 100° C.

After the polymerization reaction was completed, an intermediate product therefrom was slowly cooled to ambient temperature, and 40 g of distilled water and 400 g of methanol were added thereto and then, vigorously stirred and allowed to stand. After removing a supernatant therefrom, the precipitates therein were dissolved in 80 g of cyclohexanone and then, fervently stirred by using 320 g of methanol and allowed to stand (primary). Herein, the obtained supernatant was removed again, and the obtained precipitates were dissolved in 80 g of cyclohexanone (secondary). The primary and secondary processes were regarded as one purification process, which was repeated three times. The purified polymer was dissolved in 80 g of cyclohexanone, and the methanol and the distilled water remaining in the solution were removed under a reduced pressure to obtain a polymer represented by Chemical Formula 1-6 (Mw: 3,000 g/mol).

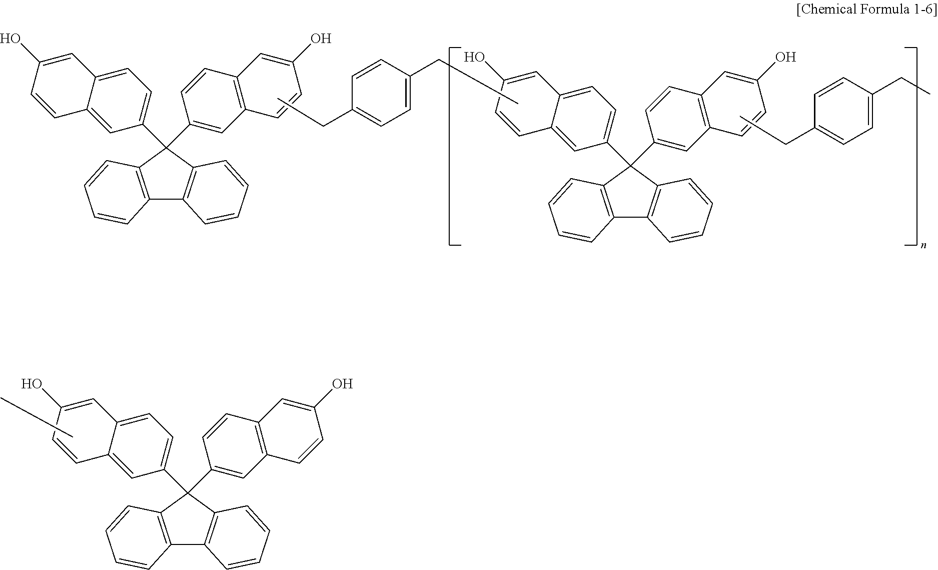

### Comparative Synthesis Example 1

A polymerization reaction was performed by adding 1 mol of 9,9-bis(6-hydroxy-2-naphthyl) fluorene, 1 mol of 4,4′-oxybis((methoxymethyl)benzene), 123 g of propylene glycol monomethylether acetate (PGMEA), and 0.5 g of diethylsulfate to a flask and then, stirring the mixture at 100° C.

After the polymerization reaction was completed, an intermediate product therefrom was slowly cooled to ambient temperature, and 40 g of distilled water and 400 g of methanol were added thereto and then, vigorously stirred and allowed to stand. After removing a supernatant therefrom, precipitates therein were dissolved in 80 g of cyclohexanone and then, vigorously stirred by using 320 g of methanol and allowed to stand (primary). Herein, the obtained supernatant was removed again, and the precipitates were dissolved in 80 g of cyclohexanone (secondary). The primary and secondary processes were regarded as one purification process, which was repeated three times. The purified polymer was dissolved in 80 g of cyclohexanone, and the methanol and the distilled water remaining in the solution were removed under a reduced pressure to obtain a polymer represented by Chemical Formula 1-7 (Mw: 3,000 g/mol).

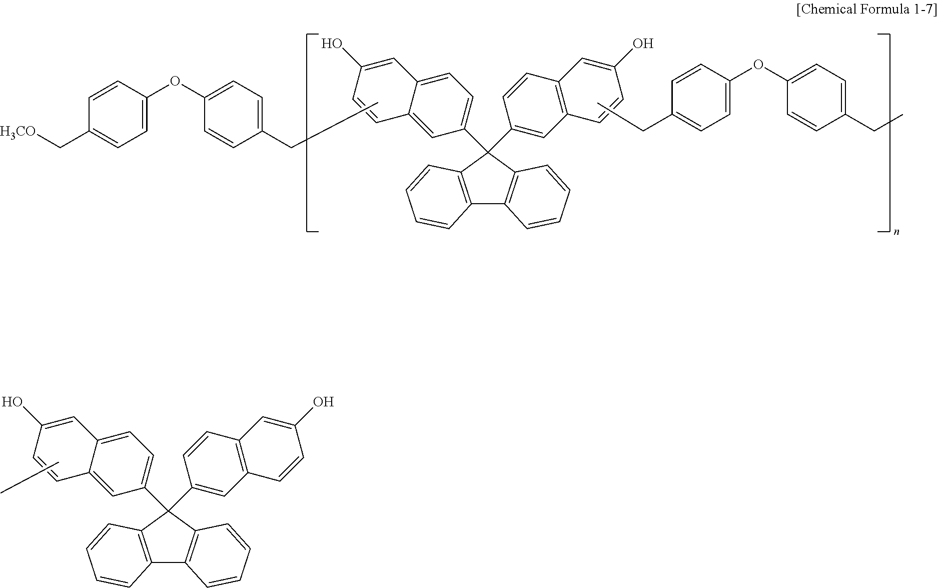

### Comparative Synthesis Example 2

A polymerization reaction was performed by adding 1 mol of 9,9-bis(3,4-dihydroxyphenyl) fluorene, 1 mol of 1,4-bis(methoxymethyl)benzene, 123 g of propylene glycol monomethyl ether acetate (PGMEA), and 0.5 g of diethylsulfate to a flask and then, stirring the mixture at 100° C.

After the polymerization reaction was completed, an intermediate product therefrom was slowly cooled to ambient temperature, and 40 g of distilled water and 400 g of methanol were added thereto and then, vigorously stirred and allowed to stand. After removing a supernatant therefrom, precipitates therein were dissolved in 80 g of cyclohexanone and then, vigorously stirred by using 320 g of methanol and allowed to stand (primary). Herein, the obtained supernatant was removed again, and the obtained precipitates were dissolved in 80 g of cyclohexanone (secondary). The primary and secondary processes were regarded as one purification process, which was repeated three times. The purified polymer was dissolved in 80 g of cyclohexanone, and the methanol and the distilled water remaining in the solution were removed under a reduced pressure to obtain a polymer represented by Chemical Formula 1-8 (Mw: 3,400 g/mol).

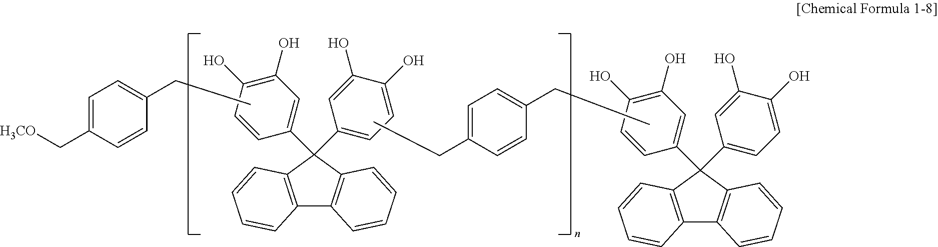

### Preparation of Hardmask Composition

### Examples 1 to 3 and Comparative Examples 1 to 2

To prepare hardmask compositions, 3 g of each of the polymers according to Synthesis Examples 1 to 3 and Comparative Synthesis Examples 1 and 2 were, respectively, dissolved in 17 g of cyclohexanone, and filtered with a 0.1 μm TEFLON (tetrafluoroethylene).

### Evaluation 1: Evaluation of Gap-Fill Characteristics and Planarization

### Characteristics

The FIGURE is a reference view illustrating a level difference of a hardmask layer to explain a method of evaluating planarization characteristics. Each of the hardmask compositions according to Examples 1 to 3 and Comparative Examples 1 to 2 was coated on each silicon pattern wafer by adjusting a mass ratio of solute to solvent to 3 to 97 and then, baked to form a 1,100 Å-thick hardmask layer. Gap-fill characteristics of the hardmask layer were evaluated by examining its pattern cross-section with a scanning electron microscope (SEM) to determine whether or not a void was generated. Planarization characteristics were evaluated by measuring and calculating an average thickness (h₁) of a thin film at any three points on a portion of a substrate with no pattern and another average thickness (h₂) of the thin film at any three points on a portion of a substrate with a pattern with a thin film thickness meter made by K-MAC to calculate a level difference (|h₁−h₂|). The smaller the level difference (|h₁−h₂|), the more excellent planarization characteristics. The results are shown in Table 1.

TABLE 1

| | Gap-fill characteristics | Planarization |
|---|---|---|
| | (Void are present or | characteristics |
| | absent) | (step, Å) |
| Example 1 | absent | 105 |
| Example 2 | absent | 103 |
| Example 3 | absent | 118 |
| Comparative Example 1 | absent | 170 |
| Comparative Example 2 | absent | 175 |

Referring to Table 1, the hardmask layers formed of the hardmask compositions according to Examples 1 to 3 exhibited excellent planarization characteristics and gap-fill characteristics, compared with the hardmask layers formed of the hardmask compositions according to the Comparative Examples.

### Evaluation 2: Solubility

Each of the polymers according to Synthesis Examples 1 to 3 and Comparative Synthesis Examples 1 and 2 was weighed and added to 20 g of ethyl lactate (hereinafter, referred to as EL), propylene glycolmonomethyl ether acetate (hereinafter, referred to as PGMEA), propylene glycolmonomethyl ether (hereinafter, referred to as PGME) to evaluate solubility. The solubility was evaluated by measuring an amount of each polymer dissolved in 20 g of each of the same solvent and converting it to a percentage as follows.

$$Solubility ( \% ) = \{ mass of polymer ( g ) / mass of solvent ( 20 g ) \}$$

TABLE 2

| | EL (%) | PGMEA (%) | PGME (%) |
|---|---|---|---|
| Example 1 | 50.7 | 38.7 | 55.7 |
| Example 2 | 37.1 | 33.5 | 47.1 |
| Example 3 | 40.2 | 34.1 | 35.8 |
| Comparative Example 1 | 13.2 | 1.5 | 10.4 |
| Comparative Example 2 | 23.4 | 0 | 26.4 |

Referring to Table 2, the polymers according to the Synthesis Examples exhibited more excellent solubility to solvents of EL, PGMEA, and PGME than the polymers of the Comparative Synthesis Examples.

By way of summation and review, according to small-sizing the pattern to be formed, it could be difficult to provide a fine pattern having an excellent profile by using only some lithographic techniques. Accordingly, an auxiliary layer, called a hardmask layer, may be formed between the material layer and the photoresist layer to provide a fine pattern.

One or more embodiments may provide a hardmask composition that can be effectively applied to a hardmask layer.

The hardmask composition formed according to some embodiments may help secure excellent solubility in solvents and may be effectively applied to a hardmask layer.

A hardmask layer formed from a hardmask composition according to some embodiments may help secure excellent gap-fill characteristics and planarization characteristics.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A hardmask composition, comprising:
a polymer represented by Chemical Formula 1; and
a solvent, 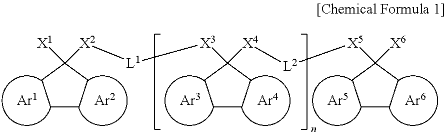
wherein, in Chemical Formula 1,
Ar¹ to Ar⁶ are each independently a substituted or unsubstituted C6 to C20 aromatic hydrocarbon ring,
X¹ to X⁶ are each independently a substituted or unsubstituted C6 to C20 aromatic hydrocarbon group,
L¹ and L² are each independently a divalent organic group, and
n is an integer of 1 to 100.

2. The hardmask composition as claimed in claim 1, wherein Ar¹ to Ar⁶ are each independently a substituted or unsubstituted aromatic hydrocarbon ring of Group 1:

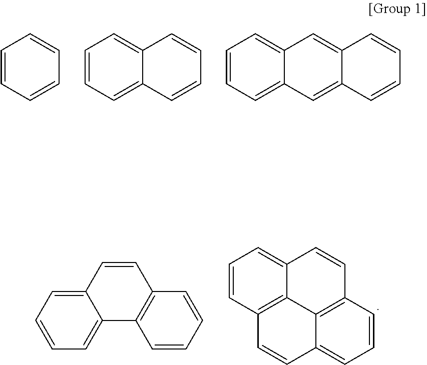

3. The hardmask composition as claimed in claim 1, wherein X¹ to X⁶ each independently include a substituted or unsubstituted moiety of Group 2:

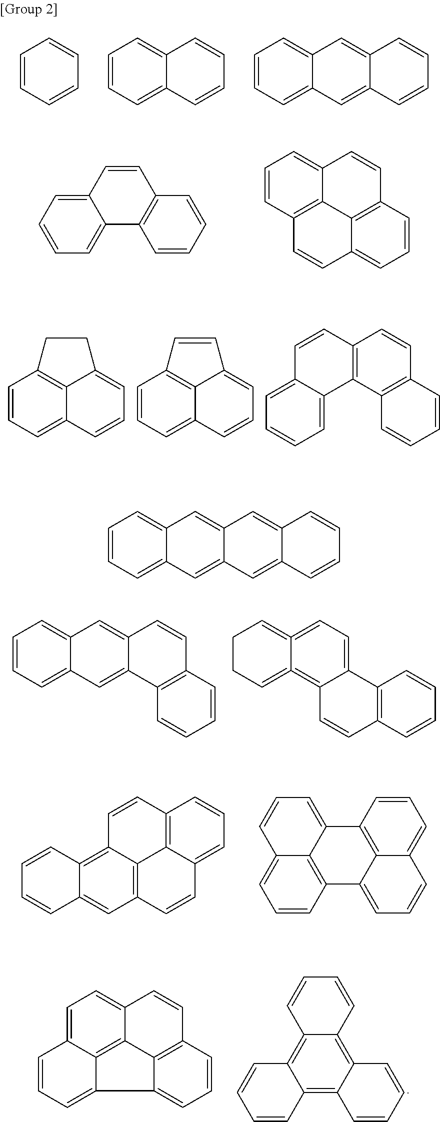

4. The hardmask composition as claimed in claim 1, wherein:
L¹ and L² are each independently represented by one of Chemical Formula 2 to Chemical Formula 5: 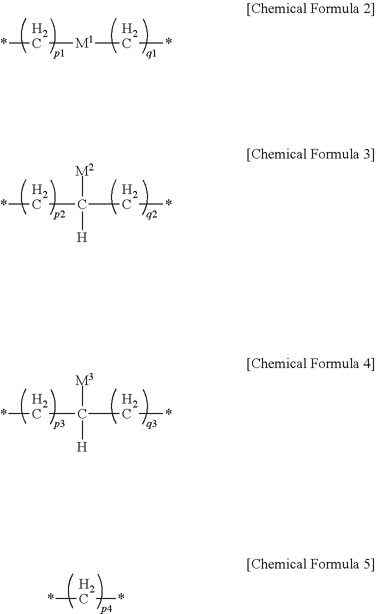
in Chemical Formula 2 to Chemical Formula 5,
M¹ to M⁴ each independently include a substituted or unsubstituted moiety of Group 3,
p1 to p3 and q1 to q3 are each independently an integer of 0 to 4,
p4 is an integer of 1 to 5, and
* is a linking point, 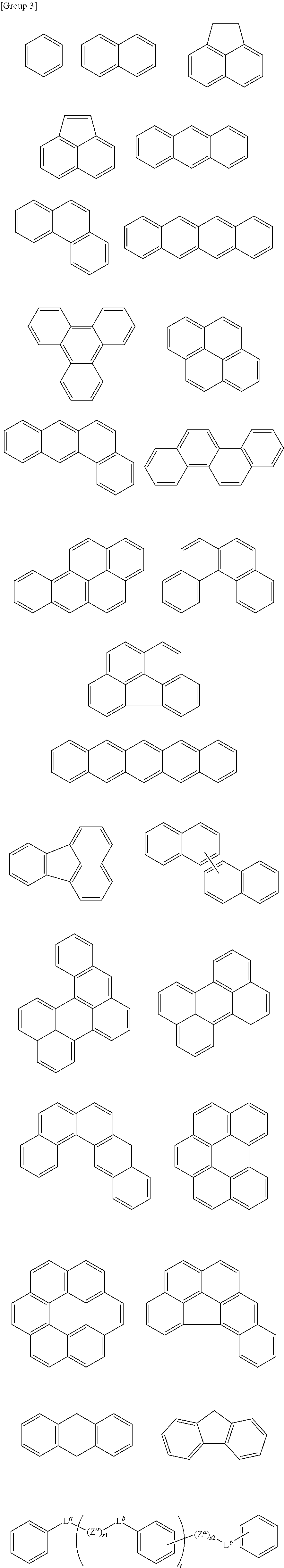
in Group 3,
L^{a} to L^{c} are each independently a single bond, a substituted or unsubstituted C1 to C10 alkylene group, a substituted or unsubstituted C2 to C10 alkenylene group, or a combination thereof,
Z^{a} and Z^{b} are each independently, —O—, —S—, —SO₂—, —C(═O)—, or —NR^{a}—, in which R^{a} is hydrogen, a substituted or unsubstituted C1 to C10 alkyl group, or a substituted or unsubstituted C6 to C20 aryl group,
s1 and s2 are each independently 0 or 1, and
t is an integer of 0 to 4.

5. The hardmask composition as claimed in claim 1, wherein:
L¹ and L² are each independently represented by one of Chemical Formula 7 to Chemical Formula 13, in which * is a linking point:

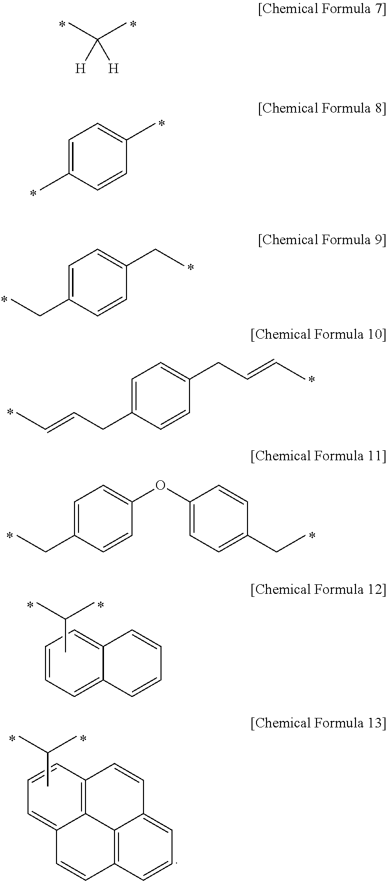

6. The hardmask composition as claimed in claim 1, wherein:
the polymer is represented by one of Chemical Formula 1-1 to Chemical Formula 1-3: 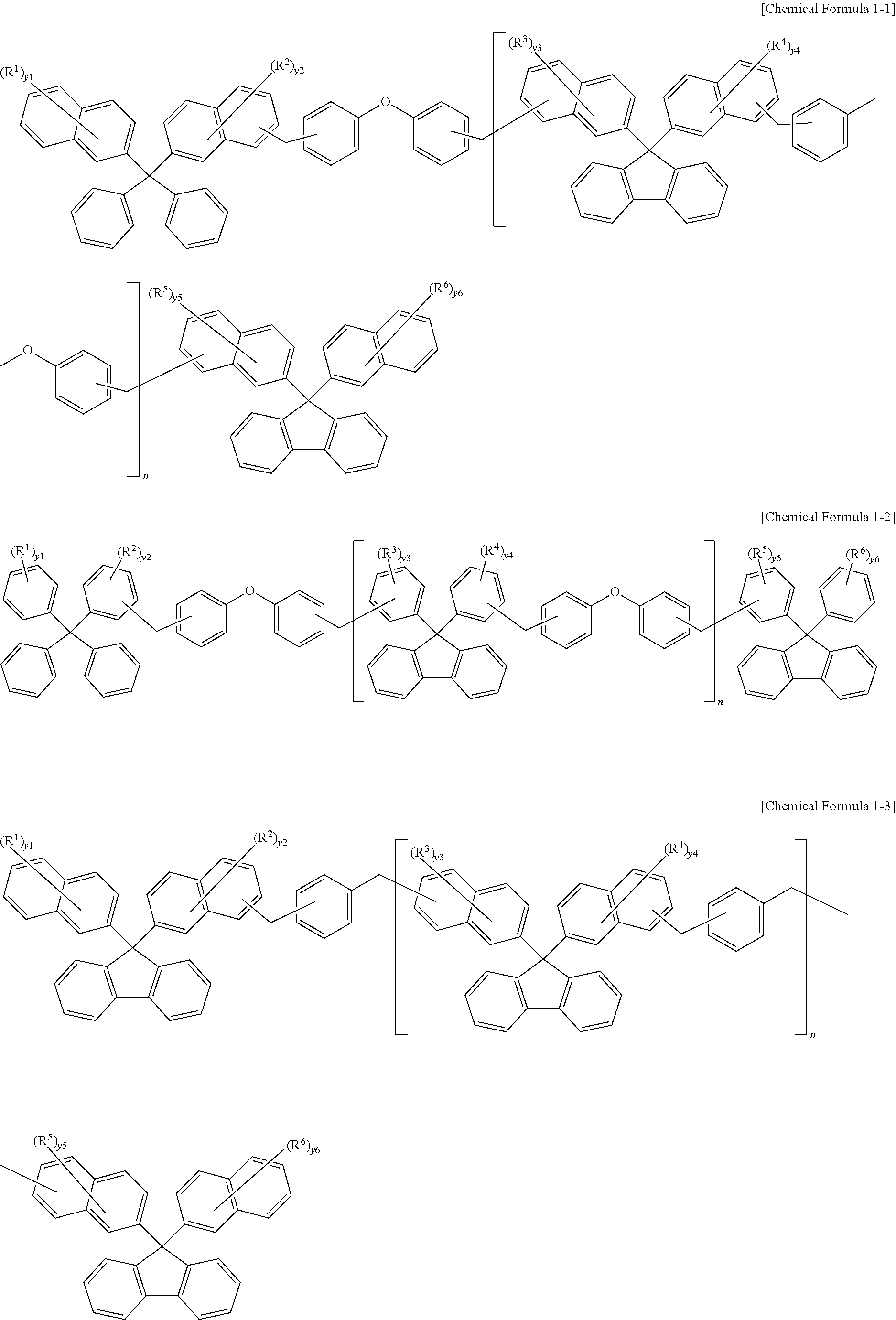
in Chemical Formula 1-1 to Chemical Formula 1-3,
R¹ to R⁶ are each independently deuterium, a hydroxy group, a substituted or unsubstituted C1 to C5 alkoxy group, a substituted or unsubstituted C1 to C5 alkyl group, or a combination thereof,
y1 to y6 are each independently an integer of 1 to 4, and
n is an integer of 1 to 100.

7. The hardmask composition as claimed in claim 1, wherein the polymer has a weight average molecular weight of about 1,000 g/mol to about 10,000 g/mol.

8. The hardmask composition as claimed in claim 1, wherein the polymer is included in an amount of about 0.1 wt % to about 30 wt %, based on a total weight of the hardmask composition.

9. The hardmask composition as claimed in claim 1, wherein the solvent is propylene glycol, propylene glycol diacetate, methoxy propanediol, diethylene glycol, diethylene glycol butylether, tri (ethylene glycol) monomethylether, propylene glycol monomethylether, propylene glycol monomethylether acetate, cyclohexanone, ethyllactate, gamma-butyrolactone, N,N-dimethyl formamide, N,N-dimethyl acetamide, N-methyl-2-pyrrolidone, acetylacetone, or ethyl 3-ethoxypropionate.

10. A hardmask layer comprising a cured product of the hardmask composition as claimed in claim 1.

11. A method of forming patterns, the method comprising:
providing a material layer on a substrate;
applying the hardmask composition as claimed in claim 1 to the material layer;
heat-treating the hardmask composition to form a hardmask layer;
forming a photoresist layer on the hardmask layer;
exposing and developing the photoresist layer to form a photoresist pattern;
selectively removing the hardmask layer using the photoresist pattern to expose a portion of the material layer; and
etching an exposed part of the material layer.

12. The method as claimed in claim 11, wherein the heat-treating is performed at about 100° C. to about 1,000° C.
